(19) United States
(12) Patent Application Publication
(10) Pub. No.: US 2026/0025953 A1
(43) Pub. Date: Jan. 22, 2026

(54) Process and Apparatus for Performing Compressed Refrigerant Thermoelectric Cooling

(71) Applicants: Nicholas Glen LITTLETON, Sherwood, OR (US); Gregory William BISSELL, Gilroy, CA (US)

(72) Inventors: Nicholas Glen LITTLETON, Sherwood, OR (US); Gregory William BISSELL, Gilroy, CA (US)

(21) Appl. No.: 19/095,565

(22) Filed: Mar. 31, 2025

Related U.S. Application Data
(63) Continuation-in-part of application No. 18/775,607, filed on Jul. 17, 2024.

(51) Int. Cl. H05K 7/20

(52) U.S. Cl. CPC H05K 7/20354; H05K 7/20136; H05K 7/20309; H05K 7/20318

(57) ABSTRACT

A refrigeration cycle coupled to a thermoelectric assembly and process for performing compressed refrigerant thermoelectric cooling of electronic equipment and other equipment that requires focused cooling of features within the product.

### CROSS-REFERENCE TO RELATED APPLICATIONS

This is a continuation-in-part application of U.S. application Ser. No. 18/775,607 filed 17 Jul. 2024, the content of which is incorporated herein by reference in its entirety.

### BACKGROUND OF THE INVENTION

### 1. Field of the Invention

The present invention relates to a cooling process and, more particularly, to a cooling process and associated system of hardware for implementing the process.

### 2. Description of the Related Art

It is known that maintaining an optimized temperature for the three primary functional semiconductor chips of a computer, i.e., the central processing unit (CPU), graphics processing unit (GPU) and the random access memory (RAM), is critical to ensuring the computer functions at an optimized performance level. It is also known that data center servers have the same components and operating conditions. When a computer or data center server is in operation or overclocked or cycled at a rate that causes the hardware to process large amounts of data and at faster rates, a significant amount of heat is generated in these three primary functional parts and within other parts of the computer or server. As this heat builds, the computer or data center server will take steps to govern the heat by engaging fans and limiting the amount of processing that the computer will undertake. This self-protection mechanism is built into the operating system of the computer or server. When these elevated temperatures are reached, the performance of the computer deteriorates, which causes lowering of data rate functions thus limiting the amount of computing power available. Without the cooling mechanisms and the reduction of the data rate, the computer would overheat, critical components would be destroyed, and the computer or data center server would be ruined. The heat a computer or data center server generates must be managed.

It is known that, in addition to the on-board thermal management systems that come with the computer, there are several different types of aftermarket enhanced heat management devices that are designed to cool the three primary functional semiconductor chips. These devices range in complexity and cost. A common type of design of these thermal management devices is a fan having an attached type of radiator. These radiators are placed on the CPU, GPU, or RAM and function as passive heat sinks and use convection for dissipating the heat into the air via direct contact and airflow.

It is known that an additional type of thermal management device for the CPU, GPU and RAM is liquid based. This device is sealed and includes a cold plate filled with liquid, or other thermal transfer fluid, which is in contact with the semiconductor chips and will serve as a heat sink, where the liquid serves as the thermal transfer mechanism for heat removal. These devices are also made with fans and radiators. They are passive and use convection in removing heat.

Active cooling apparatus that utilize a closed loop refrigeration cycle to cool semiconductor chips are also known. These devices are coupled to a water, or other working fluid, chiller that pumps cooled water to a mounting plate that is in contact with a CPU, GPU or RAM. This is a more effective method of heat reduction but is more complex and costly.

Passive water or other working fluid cooling mechanisms that only use a pump to cycle fluid to the computer and return the fluid to a radiator with a fan assembly are also known. This cooling architecture is similar to automotive type radiator based cooling systems and is referred to as direct liquid cooling.

This direct liquid cooling is also used in data center applications at large scale. In data center servers, the direct liquid cooling is infrastructure that is built into the facility and uses large pumps and manifolding hardware to distribute the liquid to all the individual servers in a data center.

Peltier plate or thermoelectric modules type cooling devices that are designed to cool CPU, GPU and RAM are additionally known. These devices use the cooling features of the Peltier plate coupled to a radiator fan assembly. These devices provide active cooling but have limited capacity because Peltier plates heat-saturate and struggle to maintain a sustained level of cooling, unless the ambient air is cool enough to keep them functional.

Many other applications that require cooling for various types of electronic gear also exist. While CPU, GPU and RAM are the most common, there are multitudes of electronics in specific applications that require cooling including server blade or rack type servers found in data centers. The above-mentioned cooling device types are all used in various forms to solve cooling problems in server applications. Some other types of electronics that require cooling are used in optics equipment, lasers, robotics, EV, communication gear, satellites, aircraft, spacecraft and various military weapons systems. Heat in electronics is ubiquitous and all electronic devices have a heat constraint that must be considered in operation.

It is known that cooling electronics have issues with condensation or any type of dense water vapor or droplets. The introduction of condensation in electrical gear is extremely dangerous. The vast majority of electronic equipment is not designed to be exposed to water. Accordingly, the cooling mechanisms designed to protect the electronics must not create condensation during the cooling process. Condensation is not an issue with passive type cooling apparatus but must be considered when active cooling mechanisms are at work. Active cooling has the potential to create temperatures lower than the dew point of the environment and may create condensation. This must be monitored in order to safeguard vulnerable electronic equipment.

### SUMMARY OF THE INVENTION

Disclosed is a compressed refrigerant thermoelectric cooling process and associated hardware for implementing the process. The disclosed process is based on the use of a compressed refrigerant coupled with thermoelectric cooling plates, which are often referred to as Peltier cooling plates or thermoelectric modules. Cooling multiple devices, semiconductor chips, other areas in a computer, other electronic device or heat sensitive equipment of any kind with compressed refrigerant and Peltier cooling plates requires the associated hardware of multiple components as well as an extensive controlling software solution to ensure synchronized process performance. The software solution can be integrated into the controlling software of the computer or electronics that is being cooled or it can be controlled by a stand-alone controller. A control system can also gather performance data of the system during operation and provide this data to the host system. The system is reliant on the hardware, associated sensor network that is monitoring system performance and a software solution to control the individual elements of the system. In the context of the instant disclosure, it is possible for an Al type control architecture to manage the operation of the system most effectively.

The hardware system includes a refrigerant compressor, evaporator, refrigerant reservoir, variable interface refrigerant flow controller or other type expansion valve or capillary tube, flexible or ridged refrigerant cooling distribution lines, an evaporator device that is coupled to a Peltier cooling plate and a refrigerant return line manifold assembly. It is possible to have a system that does not use every device depending on the application. Hybrid system architectures can be applied per specific application. In operation, these components are mechanically connected into a common refrigeration cycle, where refrigerant is compressed, condensed, expanded, evaporated and returned to the compressor to start the cycle again. This cycle effectively cools the evaporator during use, in a manner consistent with conventional refrigeration cycles.

The evaporator is typically formed as a radiator type device with tubing that is connected to metallic fins. The purpose of the evaporator is to allow the refrigerant to expand lo a lower pressure and release the cooled refrigerant energy and to effectively cool the space around the evaporator or blow air through it to perform air conditioning. Evaporators can also be constructed in other ways to include monolithic assemblies so long as they have an input and an output and provide the volumetric area for the refrigerant to expand and allow for the refrigerant to transfer cooling to the evaporator. The embodiment of an evaporator for this application is a material that has hermetic properties that can be adhered to other surfaces with a thermally conductive epoxy or mechanically attached to other surfaces with thermal conductive paste acting as the interface between the surfaces.

The system in accordance with the disclosed embodiments includes use of Peltier cooling plates in conjunction with the monolithic type evaporator assembly. In order to maintain optimized cooling effectiveness of a hot surface (e.g., a CPU in a computer or server), the Peltier cooling plate will be attached to this hot surface with thermal conductive epoxy or mechanically coupled with hardware, and a thermally conductive paste is used as the interface to the two surfaces. The monolithic evaporator will then be attached to the ‘hot’ side of the Peltier plate. It is known that Peltier plate coolers will heat saturate quickly and render their cooling effectiveness negligible. However, if the Peltier cooling plate can continuously dissipate heat, then it can maintain its function as an effective cooling apparatus. With the monolithic evaporator attached to the hot side of the Peltier plate and with the refrigeration cycle in operation, the evaporator can effectively keep the Peltier plate operating, regardless of the amount of heat that the system is dissipating. In the presently contemplated embodiment of this cooling cycle, the Peltier cooling plate is attached to the monolithic evaporator.

This cooling cycle is meant to be able to respond to various cooling requirements with near instantaneous response. Peltier cooling plates are controlled with electricity that can be signaled with energy for an immediate response. Refrigerant evaporators rely on the refrigeration cycle and need additional time to provide a cooling response. In the present embodiment of this cycle, the Peltier plate serves as the initial response to a cooling need and the evaporator cooling response and comes into effect in time to keep the Peltier plate from experiencing heat saturation. The result of this cooling response is a rapid reaction time to a cooling need and the ability to sustain cooling for as long as is needed to the capabilities of the refrigeration cycled coupled with the Peltier cooling plate. This cycle needs a sufficient control software algorithm to ensure the temperatures are being controlled with commands to distribute energy to the Peltier cooling plate in conjunction with controlling the RPM or other parameters of the refrigerant system. This cycle can also be used without the Peltier cooling plate where the monolithic evaporator assembly is directly attached to an object that also requires cooling.

The control system required to operate the hardware includes multiple thermocouples, pressure sensors, atmospheric sensors, current and voltage sensors, and a controller (e.g. a CPU, processor or microprocessor). The controller could be integrated into the computer or other electronic device through a software upload and managed within the electronic device or the controller can be a stand-alone unit or processor that executes the hardware via information received from various sensors. In operation, these sensors are placed at key places within the system hardware to forward key data to the controller to ensure the system is functioning at an optimal state. An atmospheric sensor is also added to the sensor network to ensure the system does not get cold enough to produce condensation. This atmospheric sensor measures the parameters of dew point within the environment in which the cooling system is installed. By knowing the dew point of the environment, the inventive system can ensure that temperatures of the equipment in the cycle never get low enough to create condensation that could in tum harm the electronics.

The functional requirement of the system is to control multiple heat sources by use of the hardware system that consists of one or multiple refrigerant compressors. These refrigerant compressors function to compress the returning low pressure refrigerant back to high pressure and fill a refrigerant reservoir with liquid, high-pressure refrigerant. The reservoir serves as a repository of liquid refrigerant that can be distributed to the multiple evaporators in the system by controlling the state of variable interface refrigerant flow controller. These variable interface refrigerant flow controllers are controlled by the operating software that monitors the temperature of the Peltier cooling plate that is assembled to the monolithic evaporator. This Peltier cooling plate that is assembled to the monolithic evaporator can be referred to as a cooling puck. In a functional example, if the temperature of the cooling puck starts to raise, this would signal to the system software that additional cooling requirement is needed. With this signal, the system software would instruct the variable interface refrigerant flow controller to adjust the refrigerant flow of the system and cool the evaporator and provide energy to the Peltier plate, which will cool the puck to a desired temperature. This signal could also change the rpm of the refrigerant compressor to ensure ample high-pressure refrigerant is produced to ensure system operation. In operation, an atmospheric sensor also monitors the dew point to ensure condensation is not produced by the system. If the conditions of the cooling requirement are not capable of maintaining the required temperature, then the software system can signal the host electronic device that a thermal overload condition is evident and the host system can react to ensure an overheating situation is avoided.

This presently contemplated embodiment of the control system can provide feedback to the host electronic equipment, where the cooling system can be monitored and optimized with the host electronic operating system. This exchange of data could be optimized with the use of artificial intelligence (AI).

As described, the cooling system in accordance with the disclosed embodiments can have multiple cooling pucks in operation on the same circuit as a network of cooling pucks can be integrated into the system. With one compressor, condenser and coolant reservoir, many cooling pucks can be connected. With use of the variable interface refrigerant flow controller and with sensor feedback from multiple thermocouples, the system software can effectively control each cooling puck independently of each other. This is important because electronic components do not heat uniformly and control of each cooling puck must be independent to ensure system operation and system efficiency.

It is also common that there are isolated and acute areas of electronic equipment that generate small hot spots of high heat. These are not necessarily primary components of the equipment but smaller areas of printed circuit boards (PCBs) that have high heat. It is ideal to provide cooling to these areas and current ways to manage this are known to be volumetric air flow across these areas with fans. This cooling technique is marginally effective and these hot spots are generally known and managed with high temperature resistant components. With the use of networked cooling pucks, a system of compressed and cooled air can be pinpointed exactly at the hot spots of a PCB or other area of the electronic equipment. This pinpointed directed cooled air travels through small diameter plastic or other material type tubing and is pointed directly and in very close proximity to acute areas of high heat. This method of cooling hot spots is much more effective vs common chassis fan cooling systems currently in use.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

Various embodiments are disclosed in the following detailed description and the accompanying drawings, in which:

FIG. 1A is a schematic of the process depicting the major components in accordance with the invention;

FIG. 2A is a side view of the puck assembly depicting the components of the puck assembly; and

FIG. 3A is a flow chart of the process in accordance with the invention.

### DETAILED DESCRIPTION OF THE EXEMPLARY EMBODIMENTS

The following detailed description of specific embodiments of the inventive subject matter will be better understood when read in conjunction with the appended drawings. As used herein, an element or step recited in the singular and proceeded with the word “a” or “an” should be understood as not excluding plural of said element or step, unless such exclusion is explicitly stated. Furthermore, references to “embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional elements not having that property.

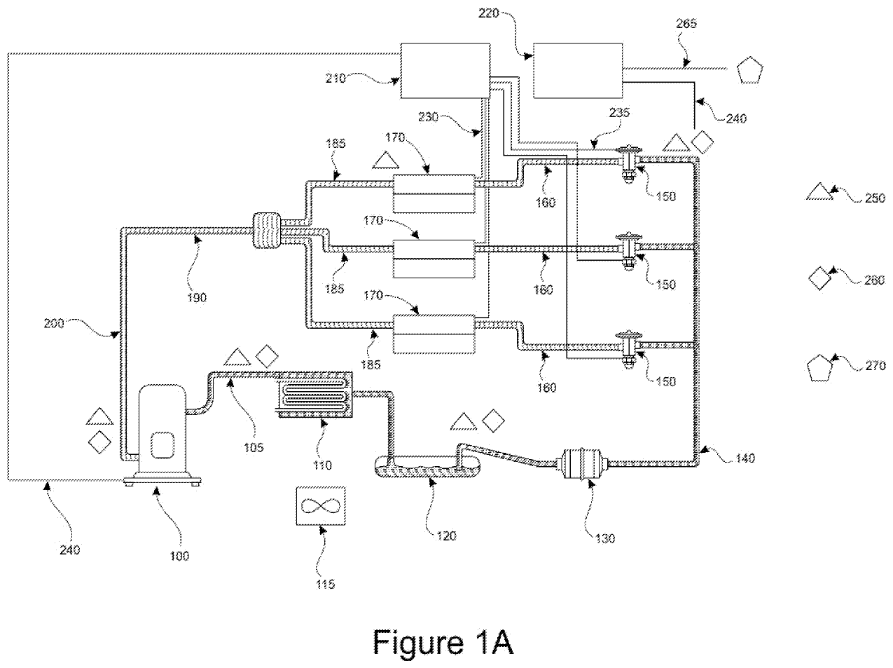

FIG. 1A is a schematic illustration of a compressed refrigerant cooling cycle used to cool multiple isolated areas of electronic equipment or other industrial products in accordance with an embodiment of the invention. As shown therein, the refrigerant cooling cycle equipment includes a refrigerant compressor 100. The refrigerant compressor 100 can be a rotary, scroll, piston or other driven compression configuration. The refrigerant compressor 100 is hermetically sealed via complete encapsulation. The refrigerant compressor 100 is controlled and powered by the compressor motor control harness 240 that is connected to either the standalone controller 210 or integrated controller 220. The refrigerant compressor 100 supplies high pressure refrigerant 105 to a refrigerant condenser 110, where the refrigerant is cooled and transitioned to a liquid or a saturated vapor state. The refrigerant condenser is cooled in ambient air or via a condenser fan assembly 115.

After the refrigerant passes through the refrigerant condenser 110, it will reside in the refrigerant receiver 120. This refrigerant receiver serves as a reservoir of refrigerant that will be available for dispatch to the remaining sections of the cooling cycle hardware. When the refrigerant leaves the refrigerant receiver 120, it will pass through a dryer filter 130 and then enter a high pressure distribution manifold 140 that provides high pressure refrigerant 105 to variable interface refrigerant flow controllers 150.

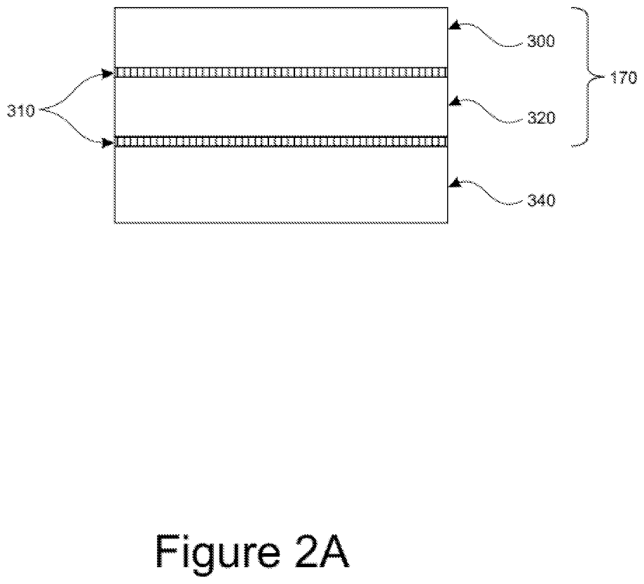

Once the refrigerant is supplied to the variable interface refrigerant flow controller 150 the controller, either the standalone controller 210 or integrated controller 220, will dispatch a setting signal through a variable interface refrigerant flow controller harness 235 to the variable interface refrigerant flow controller 150 with the correct setting for the flow controller. By changing the setting on the variable interface refrigerant flow controller 150, more or less refrigerant will travel through low-pressure puck feed line 160 to the evaporator 300. This will induce a cooling effect by dropping the pressure of the refrigerant within the evaporator 300 (see FIG. 2A).

As shown in FIG. 2A, the evaporator 300 is assembled into a puck assembly 170, which consists of the evaporator 300, thermal conductive paste 310 and a Peltier plate or thermoelectric module 320. This puck assembly 170 is attached to a heat source 340 via mechanical structure having various configurations with a layer of thermal conductive paste 310 between the two surfaces to ensure effective thermal transfer. As shown in FIG. 1A, a puck assembly 170 may also be connected to a controller 210, 220 through a puck assembly harness 230.

The puck assembly 170 performs cooling on the heat source 340 in two ways. The evaporator 300 provides cooling via refrigerant that is controlled by the variable interface refrigerant flow controller 150. The thermoelectric plate 320 provides cooling via a controlled DC voltage that is supplied from either of the controllers 210, 220. A controller may supply DC voltage into the thermoelectric plate 320 using the puck assembly harness 230. The cooling from the evaporator 300 will also serve to remove heat from the hot side of the thermoelectric module 320, which will allow the thermoelectric module 320 to rapidly adjust to variations in temperature from the heat source 340. The combination of having a variable interface refrigerant flow controller 150 controlled evaporator 300 along with a thermoelectric module 320 that is controlled within the same algorithm from the controller provides a multi-variable responsive cooling effect on the heat source.

The controllers 210, 220 monitor the heat source 340 with the use of a thermocouple sensor 250. In accordance with the disclosed embodiment, multiple thermocouple sensors 250 in the system are in communication with the controller via the sensor network harness 240. The system also includes pressure gauge sensors 260 at various locations in the system. These pressure gauge sensors 260 allow either controller 210, 220 to monitor pressures of the refrigerant at different locations within the system via the sensor network harness 240. By monitoring the thermocouple sensor 250 and pressure gauge sensor 260, it is possible for the controller algorithm or Al to make adjustments to the refrigerant compressor 100 speed, the variable interface refrigerant flow controller 150 and the thermoelectric module 320 to thereby ensure the system is optimized for the desired cooling of the heat source 340.

An additional sensor is needed to ensure the system is controlled to within a threshold of operation. An atmospheric sensor 270 is therefore used to ensure the system monitors the ambient air temperature and humidity levels. This atmospheric sensor 270 is connected to the controller with an atmospheric sensor harness 265. By monitoring the ambient air conditions, the controller algorithm or Al can guard against the creation of condensation at the areas being cooled. The creation of condensation is detrimental to many electronic devices and should be avoided.

As shown in FIG. 2A multiple puck assemblies 170 are controlled by multiple variable interface refrigerant flow controller 150, respectively. The controller algorithm or Al monitors multiple heat sources 340 and manages the cooling effect at multiple locations by manipulating the stepper motor needle valves 150, refrigerant compressor 100 and thermoelectric modules 320.

The refrigerant passes through the puck assemblies 170 and flows into the low-pressure line collection manifold 190 via the low-pressure refrigerant exhaust lines 185. The refrigerant then flows back to the refrigerant compressor 100 via the low-pressure compressor return line 200. Once the refrigerant returns to the compressor 100, the refrigerant is compressed and the cycle continues in a sustained action.

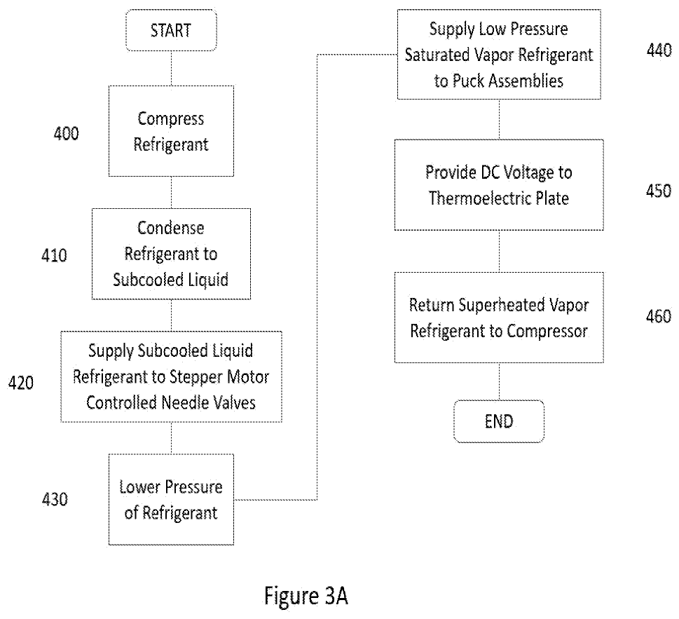

FIG. 3A is a flowchart of the process in accordance with the invention. The method comprises compressing the refrigerant, as indicated in step 400. This compression is implemented via a refrigerant compressor 100.

Next, the refrigerant is supplied to the refrigerant condenser 110 where the refrigerant is cooled and the phase of the refrigerant changes from superheated vapor to a subcooled liquid, as indicated in step 410. During this process, the heat from the refrigerant compressor 100 is removed in the refrigerant condenser 110 and dispelled into the ambient atmosphere.

Once the refrigerant is phase changed to a liquid, it is supplied to the variable interface refrigerant flow controllers, as indicated in step 420. At this point, the refrigerant is available for the evaporators as the variable interface refrigerant flow controller 150 change state and lower pressure refrigerant is created, as indicated in step 430.

Once lower pressure refrigerant is created, low pressure saturated vapor refrigerant is supplied to the evaporators 300, as indicated in step 440. As the low-pressure saturated vapor refrigerant flows through the evaporators 300, it will cool the evaporators 300 and displace heat that is being generated.

During this process, the controller 210, 220 provides DC voltage to the thermoelectric plate 320, as indicated in step 450. In this way, a cooling effect is created on the cold side of the thermoelectric module and heat is created on the hot side of the thermoelectric module. The evaporators 300 that have low pressure saturated vapor flow absorb the heat from the hot side of the thermoelectric plate 320 thus ensuring its ability to cool.

Next, the refrigerant is returned to the compressor as a superheated vapor (step 460), and the compression cycle re-starts thus providing a continuous cooling effect in accordance with the method of the invention.

While there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A cooling apparatus comprising:
a compressor;
a receiver;
a condenser connected between the compressor and the receiver;
at least one puck assembly including an evaporator and a thermoelectric module; and
a controller operatively coupled to the at least one puck assembly;
at least one variable interface refrigerant flow controller operatively coupled to the controller.

2. The apparatus of claim 1, wherein the thermoelectric module of the at least one puck assembly is further connected to a heat source.

3. The apparatus of claim 2, wherein the thermoelectric module and the heat source are separated by a thermally conductive epoxy or a thermally conductive paste.

4. The apparatus of claim 1 where the evaporator and the thermoelectric module are separated by one of a thermally conductive epoxy or a thermally conductive paste.

5. The apparatus of claim 1, wherein the controller is further connected to at least one of the compressor, the condenser, and the receiver.

6. The apparatus of claim 1, wherein the controller is integrated into an electronic device and managed via the electronic device.

7. The apparatus of claim 1, wherein the controller receives readings from at least one thermocouple sensor over a sensor network harness.

8. The apparatus of claim 1, wherein the controller receives readings from at least one pressure gauge sensor over a sensor network harness.

9. The apparatus of claim 1, wherein the controller receives readings from at least one atmospheric sensor over an atmospheric sensor harness.

10. The apparatus of claim 1, wherein the refrigerant condenser further comprises a fan assembly.

11. A method for cooling a heat source via a cooling system having a compressor, a condenser, at least one puck assembly including an evaporator, a thermoelectric module, the at least one puck assembly being connected to a heat source, a controller operatively coupled to the puck assembly and having at least one variable interface refrigerant flow controller operatively coupled to controller, the method comprising:
compressing a refrigerant via the compressor;
transferring the compressed refrigerant from the compressor to the condenser;
cooling the compressed refrigerant via the condenser;
transferring the cooled and compressed refrigerant from the condenser to the evaporator of the at least one puck assembly;
cooling the evaporator via the transferred cooled and compressed refrigerant;
applying a signal to the thermoelectric module and absorbing, by the evaporator, heat generated by the thermoelectric module to cool the thermoelectric module;
transferring refrigerant including the heat generated from the thermoelectric module to the compressor;
transferring the cooled and compressed refrigerant to the at least one variable interface refrigerant flow controller prior to transferring the cooled and compressed refrigerant to the evaporator of the at least one puck assembly; and
lowering a pressure of the cooled and compressed refrigerant via the at least one variable interface refrigerant flow controller.

12. The method of claim 11, wherein the condenser vents the heat from the refrigerant to an exterior of the condenser.

13. The method of claim 11, wherein the heat is generated by the thermoelectric module when the signal from the controller is applied to the thermoelectric module during transfer of the refrigerant to the evaporator.

14. The method of claim 11, further comprising:
transferring the cooled and compressed refrigerant to a receiver prior to transferring the cooled and compressed refrigerant to the evaporator of the at least one puck assembly.

15. The method of claim 11, further comprising:
transferring the cooled and compressed refrigerant to a receiver prior to transferring the cooled and compressed refrigerant to the at least one variable interface refrigerant flow controller.

16. The method of claim 11, further comprising:
transferring refrigerant from at least one puck assembly into a collection manifold; and
transferring the refrigerant from the collection manifold to the compressor.

17. The method of claim 11, wherein the controller further comprises:
at least one sensor harness attached to at least one of the refrigerant compressor, the refrigerant condenser, the refrigerant receiver, and the at least one puck assembly.

18. The method of claim 11, wherein the controller further comprises at least one sensor harness attached to the at least one variable interface refrigerant flow controller.

19. The method of claim 11, wherein the cooling system further comprises:
at least one thermocouple sensor connected to the system controller;
wherein the thermocouple sensor is configured to obtain a measured reading of a level of heat from the heat source; and
wherein the controller obtains the measured reading of the level of heat from the at least one thermocouple sensor, compares the measured reading to an ideal variable, and controls the cooling system in response to results of the comparison.

20. The method of claim 19, wherein the controller obtains a measured reading from one puck assembly at a time.

21. The method of claim 11, wherein the cooling system further comprises:
at least one pressure gauge sensor connected to the system controller,
wherein the at least one pressure gauge sensor is configured to obtain a measured reading of refrigerant pressure, obtains the measured pressure reading from the pressure gauge sensor, compares the measured pressure reading to an ideal variable, and controls the cooling system in response to results of the comparison.

22. The method of claim 11, wherein the compressed refrigerant cooling system further comprises:
at least one atmospheric sensor;
wherein the atmospheric sensor is configured to obtain a measured reading of a dew point of the ambient environment; and
wherein the controller obtains the measured reading of the dew point from the atmospheric sensor, compares the measured reading of the dew point to an ideal variable, and controls the cooling system in response to results of the comparison.

23. A method for cooling a heat source via a cooling system having a compressor, a condenser, at least one puck assembly including an evaporator, the at least one puck assembly being connected to a heat source, a controller operatively coupled to the puck assembly and having at least one variable interface refrigerant flow controller operatively coupled to controller, the method comprising:
compressing a refrigerant via the compressor;
transferring the compressed refrigerant from the compressor to the condenser;
cooling the compressed refrigerant via the condenser;
transferring the cooled and compressed refrigerant from the condenser to the evaporator of the at least one puck assembly;
cooling the evaporator via the transferred cooled and compressed refrigerant;
transferring the cooled and compressed refrigerant to the at least one variable interface refrigerant flow controller prior to transferring the cooled and compressed refrigerant to the evaporator of the at least one puck assembly; and
lowering a pressure of the cooled and compressed refrigerant via the at least one variable interface refrigerant flow controller.
